(19) United States
(12) Patent Application Publication
(10) Pub. No.: US 2015/0185538 A1
(43) Pub. Date: Jul. 2, 2015

(54) DISPLAY DEVICE AND TELEVISION RECEIVER

(71) Applicant: SHARP KABUSHIKI KAISHA, Osaka-shi, Osaka (JP)

(72) Inventors: Toshihiro Yamamichi, Osaka-shi (JP); Hiroki Iwata, Osaka-shi (JP)

(73) Assignee: SHARP KABUSHIKI KAISHA, Osaka-shi, Osaka (JP)

(21) Appl. No.: 14/409,998

(22) PCT Filed: Jun. 20, 2013
(86) PCT No.: PCT/JP2013/066904

§ 371 Date: Dec. 19, 2014

(30) Foreign Application Priority Data
Jun. 22, 2012 (JP) 2012-141233
Mar. 19, 2013 (JP) 2013-056886

(51) Int. Cl. G02F 1/1333; H04N 5/44; H05K 5/00

(52) U.S. Cl. CPC G02F 1/133308; H05K 5/0008; H04N 5/44; G02F 2001/133314; G02F 2001/13332

(57) ABSTRACT

Provided are a display device which is capable of suppressing occurrence of defective products due to fastening defect of screws, having excellent productivity, workability, and maintenance management properties, achieving narrowing of frame and thinning of set thickness with excellent quality, and manufacturing at a low cost, as well as a television receiver including the display device. A TV receiver includes a display module, and horizontal frames which cover long side peripheral end parts of a front surface of the display module. A screwing part of the fixing member is provided with female screw. The horizontal frame includes an end edge covering part which covers a long side end edge part of the display module and a side covering part which covers a side thereof, and a protruding part which protrudes inwardly of the side covering part. The protruding part is provided with screw insertion hole and notches. The screwing part is inserted from the notch, moved along the protruding part 43, the screw is inserted into the screw insertion hole and screwed to the female screw 81g, and thereby the display module locked to the fixing member is fixed to the horizontal frame.

### CROSS-REFERENCE TO RELATED APPLICATIONS

This application is the National Phase of PCT International Application No. PCT/JP2013/066904, filed on Jun. 20, 2013, which claims priority under 35 U.S.C. 119(a) to Patent Application No. 2012-141233, filed in Japan on Jun. 22, 2012 and No. 2013-056886, filed in Japan on Mar. 19, 2013, all of which are hereby expressly incorporated by reference into the present application.

### BACKGROUND

1. Technical Field

The present invention relates to a display device which includes a display unit, and a rectangular frame covering the peripheral edge part of the display unit, and in which a fixing member is screwed to the frame so as to fix the display unit to the frame, with a locking part provided in the fixing member locked, and a television receiver including the display device.

2. Description of Related Art

Recently, the size of a thin type television receiver (hereinafter, referred to as a TV receiver) including a liquid crystal display, or the like is becoming larger, and the number of models thereof such as 52, 60 and 70 inch display sizes is increasing as well. The display device includes a display module having a display surface for displaying an image on a front side thereof, a front cabinet which encloses peripheral edge parts of the display module, and a rear cabinet which covers a rear side of the display module. As the display size is becoming larger, and a cabinet forming the appearance of the television is also becoming larger, but a desire to make the outer size as small as possible is also strong. Therefore, narrow frame products in which a frame portion of the front cabinet is made narrow are also on sale.

FIG. 1 is a partial longitudinal sectional view illustrating a conventional TV receiver 69. In the drawing, the rear cabinet is not illustrated.

The TV receiver 69 includes a display module 2, a front cabinet 3 covering peripheral edge parts of the display module 2, a front bezel 14, and a rear bezel 15. The front cabinet 3 includes a horizontal frame 30 and a vertical frame (not illustrated).

The display module 2 includes a liquid crystal display panel (hereinafter, referred to as a display panel) 21, three optical sheets 22, a diffusion plate 23, a reflection sheet 24, and a chassis 25.

The reflection sheet 24 has a flat plate part, an inclination part rising from a peripheral edge of the flat plate part, and an edge part protruding from an end edge of the inclination part.

The chassis 25 is for example, formed in a box shape by molding a metal plate, and has a flat plate part 25a which is formed in a rectangular shape, a frame part 25b which is formed so as to vertically rise from a peripheral edge of the flat plate part 25a, an edge part 25c which is disposed so as to protrude from an end of the frame part 25b to an outside of the box shape substantially parallel to the flat plate part 25a, and a protruding part 25d which is disposed so as to protrude from an end edge portion of the edge part 25c substantially parallel to the frame part 25b. A plurality of LED substrates (not illustrated) are disposed on the flat plate part of the chassis 25 side by side in the short side direction of the flat plate part.

The rear bezel 15 is formed in a frame shape to cover a peripheral edge part of the optical sheet 22, and integrally holds the optical sheet 22 and the diffusion plate 23, and the reflection sheet 24 and the edge part 25c of the chassis 25. The front bezel 14 is formed in a frame shape with a size capable of housing the rear bezel 15, and covers a peripheral portion of the display panel 21, and further integrally holds the optical sheet 22, the diffusion plate 23, the reflection sheet 24, and the chassis 25 which are integrally held by the rear bezel 15, and the display panel 21.

The horizontal frame 30 includes an end edge covering part 31 which covers end edge parts of a front surface of the display module 2, a side covering part 32 which is continuously arranged orthogonal to the end edge covering part 31 and covers a side part of the display module 2, and a projection 33 which is provided on a boundary portion side with the side covering part 32 of the end edge covering part 31, and has a prescribed length. The projection 33 is provided with a female screw 34 in a central portion in a lateral direction thereof.

A fixing member 60 includes a screwing part 61 which extends in a narrow plate shape, an extension part 62 which is continuously arranged orthogonal to a long side of the screwing part 61 and extending in a plate shape, a first locking plate part 63 which is continuously arranged orthogonal to the extension part 62, and a second locking plate part 64 which is continuously arranged orthogonal to the first locking plate part 63. The screwing part 61 is provided with a screw insertion hole 61a in the central portion in a longitudinal direction thereof.

With the screwing part 61 abutting the projection 33, a tip end portion of a protruding part 25d of the chassis 25 abutting a front surface of the first locking plate part 63, and a tip end portion of the second locking plate part 64 abutting a rear surface of an edge part 25c, that is, with the fixing member 60 locked to the chassis 25, a screw 35 is inserted into the screw insertion hole 61a, and screwed to the female screw 34, and thereby the display module 2 is fixed to the horizontal frame 30.

In addition, as another structure for fixing the display module to the front cabinet, Japanese Patent Laid-open Publication No. 2009-42537 discloses a structure which includes a plurality of flexible hook claws protruding rearward from an outer peripheral part of the front cabinet, and the front cabinet is fixed to the display module by the hook claws.

[symbol]

### SUMMARY

Recently, in the display device of the TV receiver, in order to improve design properties and narrowing of the frame, aluminum has been often used as a material of the front cabinet. However, when the front cabinet is made of aluminum, there are problems that freedom of shape is low, and since tapping for forming a screw hole for screwing is a post-process, costs are increased, compared to a case wherein the front cabinet is made of plastic.

In addition, as described above, when the display module is fixed to the front cabinet through the fixing member, and screw holes (female screws) are formed in the front cabinet to allow for the fastening with screws, stainless steel, or the like is often used as a material of the fixing member. If the front cabinet is made of aluminum, which is likely to cause screw damage, defective products often occur due to fastening defect or the like. When defective products occur, replacing the front cabinet is required, and therefore there is a problem that F cost (cost for the occurrence of the defective products) may be significantly increased.

As a measure for this, when a torque of the screw is set to be weak, since the torque of the screw is different from the other parts, it is necessary to manage the torque of the connecting portions and the torque of the other portions separately, and thereby there are problems in which productivity and workability may be deteriorated. In addition, when making the screw damage less likely to occur by increasing the length of the screw, there is a problem that a set thickness of the TV receiver may be increased.

In addition, since the thick projection 33, or the like for fixing screws to the front cabinet is required in the above-described conventional fixing structure, that is, the cross-section of the front cabinet becomes non-uniform, it is necessary to decrease the extrusion rate during molding, which may cause a decrease in productivity. Further, there are problems that a sink which occurs as the thick part is recessed is viewed from an outside in a streak shape to cause warping of the frame in the longitudinal direction, or the like, which may lead a deterioration in quality.

Further, the TV receiver disclosed in Japanese Patent Laid-open Publication No. 2009-42537 has a problem that it is difficult to remove the front cabinet form the display module during maintenance. Specifically, when removing the display module from the front cabinet, there is a need to remove a plurality of claw hooks which are caught around the display module in order. However, during this process, the removed hook claws are often again caught on the display module. Therefore, there is a need to remove the display module by a plurality of operators, or insert a member such as a wedge between the hook claw and the display module, so that a hook claw that has been removed once is not caught again on the display module. When the size of the display device is large, these problems are particularly prominent, and maintainability is deteriorated.

In consideration of the above-mentioned circumstances, it is an object of the present invention to provide a display device which is capable of suppressing occurrence of defective products due to fastening defect of screws, having excellent productivity, workability, and maintenance management properties, achieving narrowing of frame and thinning of set thickness with excellent appearance quality, and manufacturing at a low cost, as well as a television receiver including the display device.

According to an aspect of the present invention, there is provided a display device which includes a display unit which displays an image on the front surface, a rectangular frame covering the peripheral edge part of the display unit, and a fixing member having: a screwing part to which the frame is screwed; an extension part which extends to a rear side along a side part of the display unit; and a locking part which is locked to the rear side of the display unit, wherein the screwing part is provided with a female screw for screwing the frame.

In the display device according to the present invention, the frame has an end edge covering part which covers an end edge part of the front surface of the display unit, and a side covering part which covers a side part of the display unit, the side covering part has a protruding part which protrudes substantially parallel to the end edge covering part on the inward side, the protruding part is provided with an insertion hole into which a screw is inserted, and the screwing part is configured to be inserted between the protruding part and the end edge covering part so that the protruding part is screwed to the screwing part.

In the display device according to the present invention, the protruding part is provided with an insertion hole into which the fixing member is inserted, and the fixing member is configured to be inserted from the insertion hole so that the screwing part is moved along the protruding part.

In the display device according to the present invention, the screwing part is provided with a stopper which is locked to a side of the insertion holes.

In the display device according to the present invention, the screwing part has a U-shaped cross-section in a longitudinal direction.

In the display device according to the present invention, the screwing part has a flat plate part which has a rectangular shape, and a spring which is provided on the rear surface of the flat plate part to press the flat plate part to the protruding part.

In the display device according to the present invention, the locking part has an L-shape when viewed from a side.

According to another aspect of the present invention, there is provided a television receiver including: the above-described display device; and a receiving part which receives a television broadcast, wherein the display device is configured to display an image based on the television broadcast received by the receiving part.

According to the present invention, since the female screw is provided in the fixing member using a harder metal than the frame, occurrence of defective products due to fastening defect such as screw damage, or the like may be suppressed, and even when replacement of the fixing member is required due to occurrence of the screw damage, only the fixing member with the damaged screw may be replaced, and therefore replacement costs and F costs may be reduced. In addition, tapping in the manufacture of the frame may be removed, and therefore overall cost may be reduced.

Further, a length of the screw may be shortened, and the set thickness may be reduced by arranging the fixing member closer to the frame side. Furthermore, since thickening measures of the frame are not required, it is possible to achieve narrowing of the frame.

In addition, since the frame may have a uniform cross-section shape, the productivity of the frame may be improved, and since the volume thereof is decreased, such that material costs may be reduced, and thereby overall cost may be reduced. Further, poor appearance such as impairment of appearance caused by that the shape of a thick portion is reflected, or the like may be suppressed, without occurring the warping of the frame in the longitudinal direction, while having excellent appearance quality.

Furthermore, when the fixing member has a spring, it is possible to absorb dispersions in the width dimension of the frame, and with respect to a television receiver having a different width of the frame, it is possible to share the fixing member.

The above and further objects and features will more fully be apparent from the following detailed description with accompanying drawings.

### BRIEF DESCRIPTION OF THE SEVERAL VIEWS OF THE DRAWINGS

FIG. 1 is a partial longitudinal sectional view illustrating a conventional TV receiver;

FIG. 2 is a front perspective view illustrating an appearance of a TV receiver according to Embodiment 1 of the present invention;

FIG. 3 is a rear view illustrating a state in which a rear cabinet of the TV receiver according to Embodiment 1 of the present invention is removed;

FIG. 4 is a partially enlarged view of FIG. 3;

FIG. 5 is a perspective view of a portion of FIG. 4;

FIG. 6 is a partial longitudinal sectional view illustrating a state in which the rear cabinet is removed;

FIG. 7 is a rear view illustrating a front cabinet;

FIG. 8 is a partially enlarged view of FIG. 7;

FIG. 9 is a perspective view of a portion of FIG. 8:

FIG. 10 is a perspective view illustrating a connector;

FIG. 11 is a perspective view illustrating a state in which a horizontal frame and a vertical frame are connected to each other by the connector;

FIG. 12 is a perspective view illustrating a fixing member;

FIG. 13 is a front view illustrating the fixing member;

FIG. 14 is a plan view for describing the attachment of the fixing member to the horizontal frame;

FIG. 15 is a side view for describing the attachment of the fixing member to the horizontal frame;

FIG. 16 is a partial longitudinal sectional view illustrating a TV receiver according to Embodiment 2 of the present invention;

FIG. 17 is a perspective view illustrating a fixing member according to Embodiment 3 of the present invention;

FIG. 18 is a front view illustrating the fixing member;

FIG. 19 is a side view for describing the attachment of the fixing member to the horizontal frame.

### DETAILED DESCRIPTION

Hereinafter, the present invention will be described in detail with reference to the accompanying drawings illustrating the embodiments thereof.

### Embodiment 1

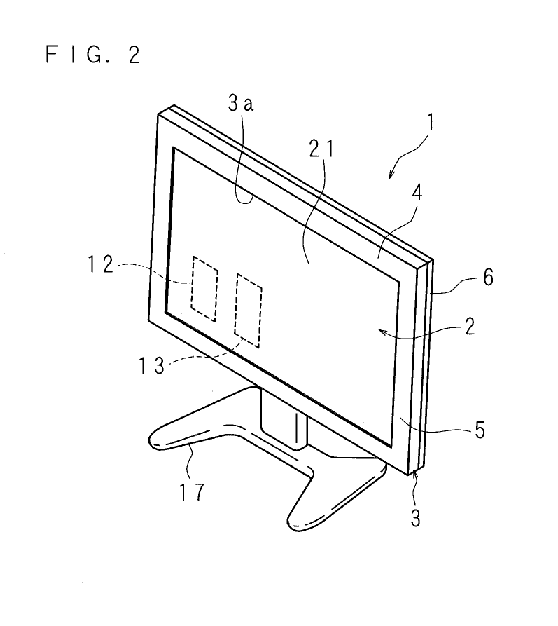

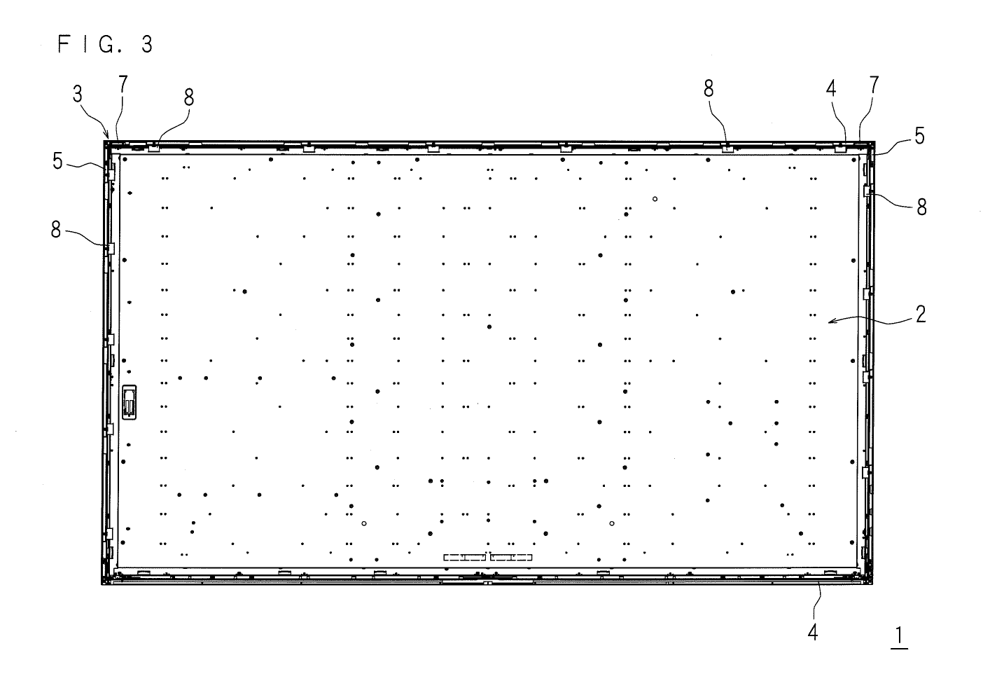

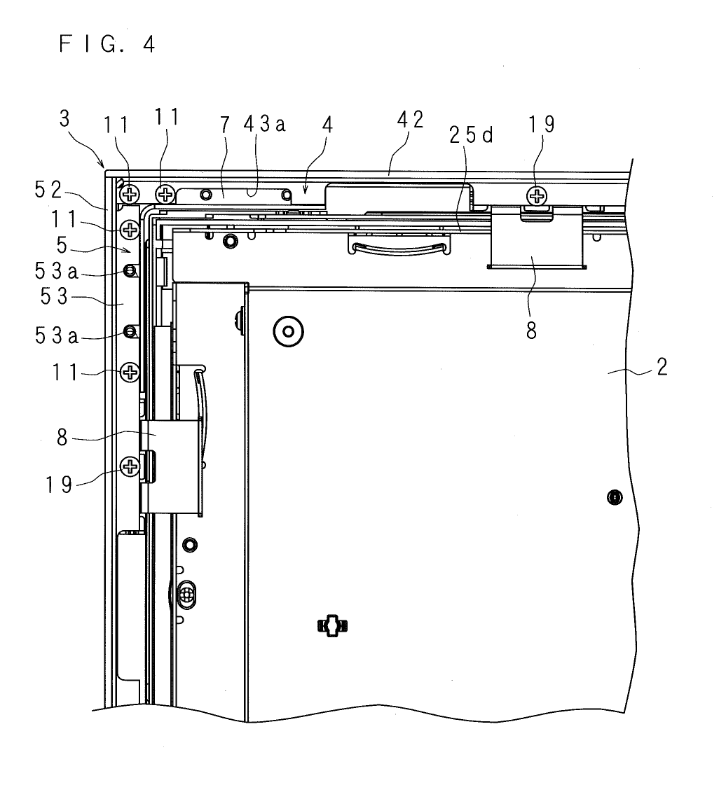

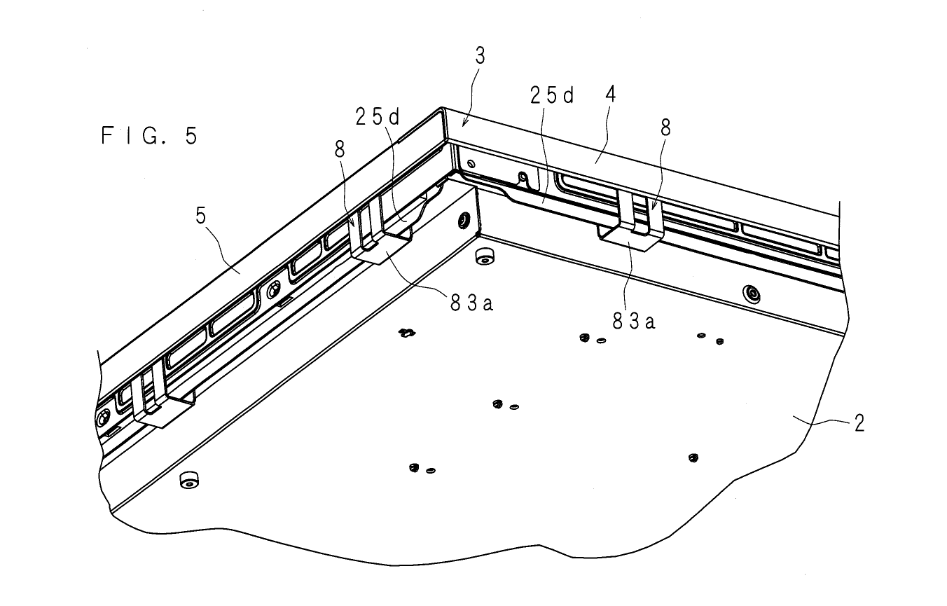

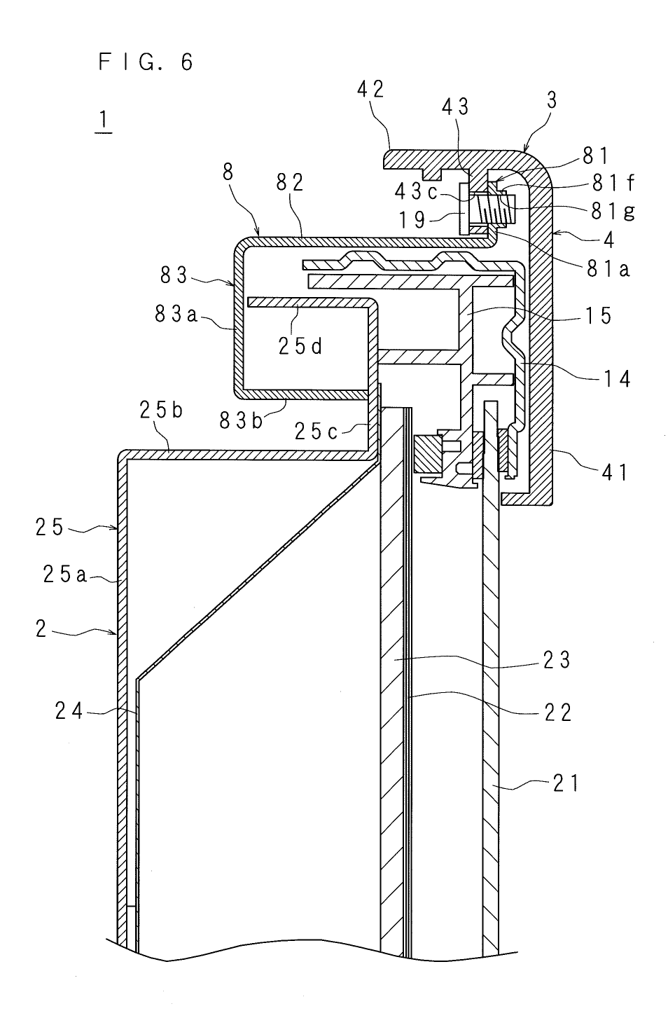

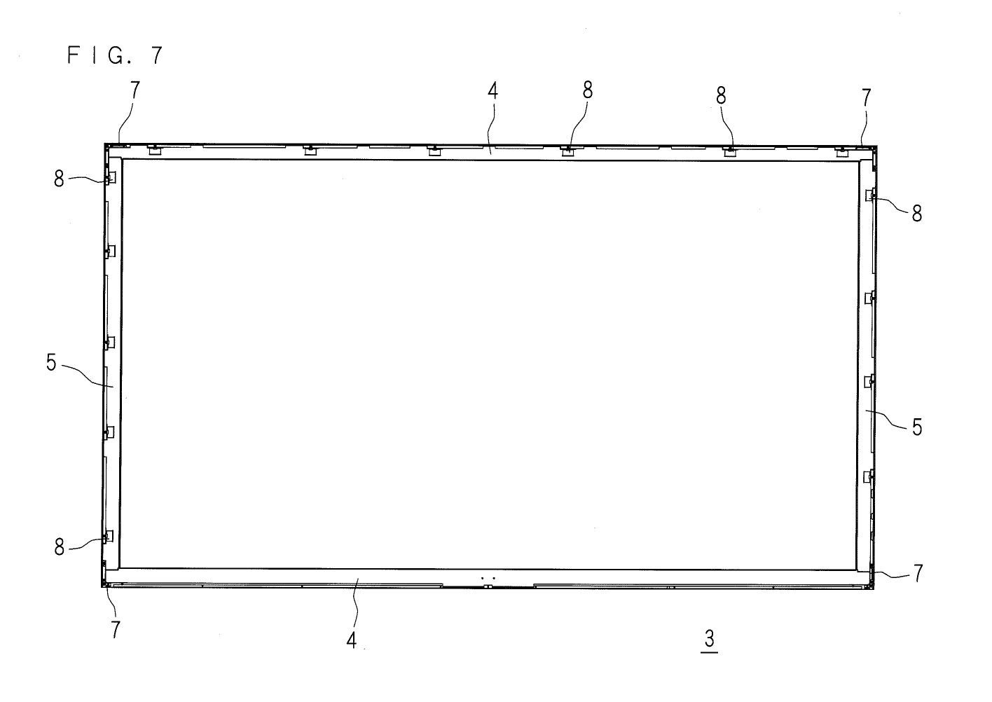

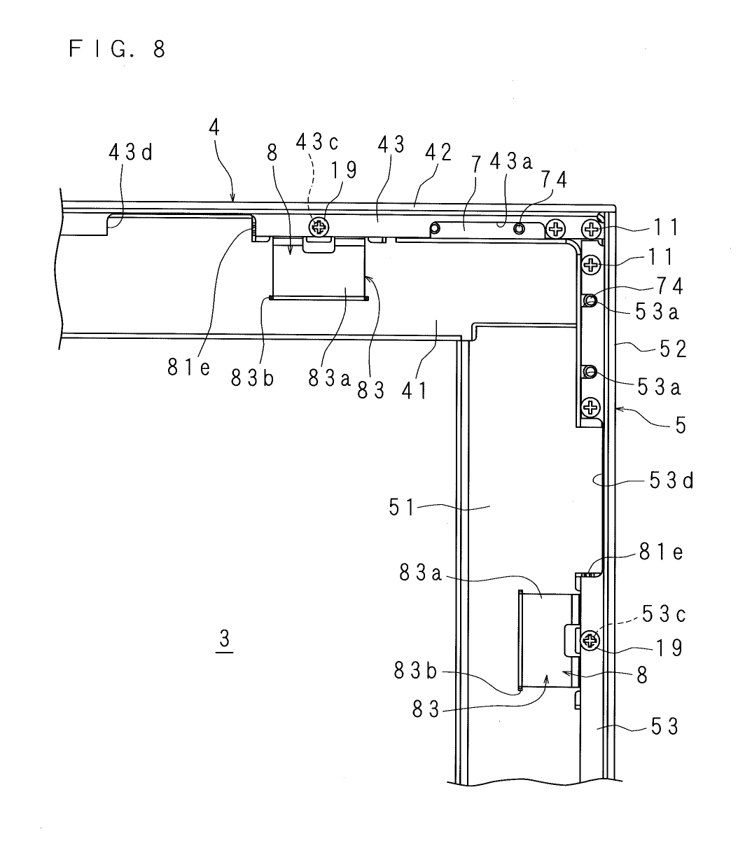

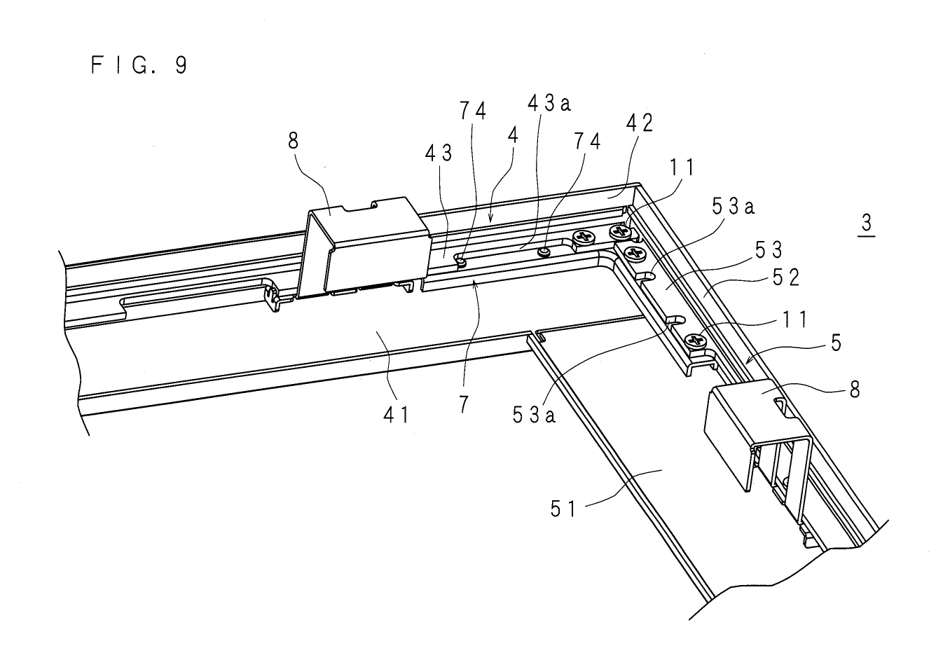

FIG. 2 is a front perspective view illustrating an appearance of a TV receiver according to Embodiment 1 of the present invention, FIG. 3 is a rear view illustrating a state in which a rear cabinet of the TV receiver 1 according to Embodiment 1 of the present invention is removed, FIG. 4 is a partially enlarged view of FIG. 3, FIG. 5 is a perspective view of a portion of FIG. 4, FIG. 6 is a partial longitudinal sectional view illustrating a state in which the rear cabinet is removed, FIG. 7 is a rear view illustrating a front cabinet, FIG. 8 is a partially enlarged view of FIG. 7, and FIG. 9 is a perspective view of a portion of FIG. 8.

A TV receiver 1 includes a laterally long display module 2 for displaying an image thereon, a tuner 12 which is disposed in the display module 2 to receive a broadcast wave from an antenna (not illustrated), and a decoder 13 which is disposed in the display module 2 to decode the encoded broadcast wave. In the TV receiver 1, the decoder 13 decodes the broadcast wave received by the tuner 12, and the display module 2 displays an image based on decoded information. The TV receiver 1 is provided with a stand 17 for supporting the TV receiver 1 at a lower side thereof.

The display module 2 includes a laterally long rectangular display panel 21 having a display surface on a front side thereof. The display panel 21 is housed longitudinally between a front cabinet 3 and a rear cabinet 6 disposed longitudinally in front and back respectively. The front cabinet 3 is a rectangular frame for covering the peripheral edge part of the display panel 21, and has a rectangular opening 3a in the center thereof. The front cabinet 3 is made of aluminum, for example. The rear cabinet 6 is formed in a rectangular tray shape with the front side open, and is made of electro-galvanized steel plate, for example. Further, the front cabinet 3 and the rear cabinet 6 may be made of other material as well.

The vertical and lateral dimensions of the front cabinet 3 and the rear cabinet 6 are substantially the same, and peripheral edge portions thereof face each other. The vertical and lateral dimensions of the display panel 21 are slightly larger than those of the opening 3a of the front cabinet 3, and the peripheral edge part of the display panel 21 faces an inner edge part of the front cabinet 3.

As illustrated in FIG. 3, the front cabinet 3 includes a pair of horizontal frames 4 which cover long side end edge parts of a front surface and sides of the display module 2, a pair of vertical frames 5 which cover short side end edge parts of the front surface and sides of the display module 2, and four connectors 7 which connect end portions of the adjacent horizontal frame 4 and the vertical frame 5. The connector 7 may be made of stainless steel, for example.

As illustrated in FIGS. 7 to 9, the horizontal frame 4 includes an end edge covering part 41 which extends in a plate shape so as to be along a long side of the display module 2, a side covering part 42 which is continuously arranged so as to be orthogonal to the end edge covering part 41, and extends in the plate shape so as to be along the side part of the display module 2, and a plate-shaped protruding part 43 which protrudes inwardly from the side covering part 42 near the end edge covering part 41 substantially parallel to the end edge covering part 41. A width of the end edge covering part 41 is larger than the width of the side covering part 42, and as an example, a width of the protruding part 43 is substantially ¼ of the width of end edge covering part 41. A notch 43a having a prescribed length is provided in an inner end edge portion of the protruding part 43 at a longitudinal direction connecting side thereof. In addition, a notch 43d having a longer length than the notch 43a is provided in the protruding part near a central portion in a longitudinal direction at a prescribed interval from the notch 43a. The notch 43d has a length that a screwing part 81 of a fixing member 8 to be described below can be inserted.

Further, a screw insertion hole 43c is provided between the notch 43a and the notch 43d.

The vertical frame 5 includes an end edge covering part 51 which extends in a plate shape along a short side of the display module 2, a side covering part 52 which is continuously arranged so as to be orthogonal to the end edge covering part 51, and extends in the plate shape along the side part of the display module 2, and a plate-shaped protruding part 53 which protrudes inwardly from the side covering part 52 near the end edge covering part 51 substantially parallel to the end edge covering part 51. A width of the end edge covering part 51 is larger than the width of the side covering part 52, and as an example, a width of the protruding part 53 is substantially ¼ of the width of end edge covering part 51. Narrow notches 53a and 53a are provided at two places in an inner end edge portion of the protruding part 53 at a longitudinal direction connecting side thereof. In addition, a notch 53d having a longer length than the notch 53a is provided in the protruding part near the central portion at a prescribed interval from the notch 53a of the central portion side in a longitudinal direction. The notch 53d has a length that the screwing part 81 of the fixing member 8 to be described below can be inserted.

While keeping each side of the connector 7 formed in a substantially L shape close to the inner side (front side of the TV receiver 1) of end portions of the respective protruding parts 43 and 53, and a projection 74 of the connector 7 to be described below is locked to the notches 43a, 53a and 53a, the horizontal frame 4 and the vertical frame 5 are connected to each other by screwing with screws 11, and thereby the front cabinet 3 is obtained. A detailed attaching structure of the connector 7 will be described below.

As illustrated in FIGS. 3 to 6, the display module 2 is fixed to the connected horizontal frame 4 and the vertical frame 5 by the fixing member 8. The fixing member 8 may be made of stainless steel, for example.

The display module 2 includes the display panel 21, three optical sheets 22, a diffusion plate 23, a reflection sheet 24, and a chassis 25. The optical sheets 22, the diffusion plate 23, the reflection sheet 24, and the chassis 25 form a backlight unit.

The reflection sheet 24 is a white sheet, and for example, may be made of a resin material having an optical reflectivity such as polyethylene terephthalate (PET), polycarbonate (PC) or the like. The reflection sheet 24 has a flat plate part, an inclination part rising from a peripheral edge of the flat plate part, and an edge part protruding from an end edge of the inclination part. The flat plate part has a rectangular shape.

The chassis 25 is for example, formed in a box shape by molding a metal plate, and has a flat plate part 25a which has a rectangular shape, a frame part 25b which is formed so as to vertically rise from a peripheral edge of the flat plate part 25a, an edge part 25c which is disposed so as to protrude from an end edge portion of the frame part 25b to an outside of the box shape substantially parallel to the flat plate part 25a, and a protruding part 25d which is disposed so as to protrude from an end edge portion of the edge part 25c substantially parallel to the frame part 25b.

A plurality of LED substrates (not illustrated) are disposed on the flat plate part 25a of the chassis 25 side by side in the short side direction of the flat plate part 25a. Each LED substrate includes a substrate, LEDs, and lenses. The substrate is formed in an elongated rectangular shape. A plurality of LEDs are mounted on the substrate in a row in the longitudinal direction.

Herein, a light source of the backlight unit is not limited to the LED, and it may be a cold-cathode tube or the like. In addition, the backlight unit is not limited to a direct type, and it may be an edge light type.

The display panel 21 has a liquid crystal layer, a pair of glass substrates, and polarizing plates. The pair of glass substrates is bonded to each other across a seal material, and the liquid crystal layer is held between them. In addition, the polarizing plates are respectively disposed on the surfaces of the sides opposite to the liquid crystal layer sides of the pair of glass substrates.

The diffusion plate 23 has a main surface which is formed in a relatively thick rectangular plate shape, and faces the display panel 21 side, and a rear surface which is an opposite surface of the main surface and faces the chassis 25, a pair of long sides, and a pair of short sides. In addition, light introduced into the diffusion plate 23 from the rear side is diffused and emitted toward the display panel 21 side from the main surface of the diffusion plate 23.

The optical sheets 22 are a sheet group including a diffusion sheet, prism sheet, DBEF sheet (reflection type polarizing sheet), or the like, and are placed on the main surface of the diffusion plate 23. In addition, collection, etc. of the light emitted from the main surface of the diffusion plate 23 is performed by the optical sheets 22.

A rear bezel 15 is formed in a frame shape to cover a peripheral edge part of the optical sheet 22, and integrally holds the optical sheet 22 and the diffusion plate 23, and the reflection sheet 24 and the edge part 25c of the chassis 25. A front bezel 14 is formed in a frame shape with a size capable of housing the rear bezel 15, and covers a peripheral portion of the display panel 21, and further integrally holds the optical sheet 22, the diffusion plate 23, the reflection sheet 24, and the chassis 25 which are integrally held by the rear bezel 15, and the display panel 21.

The fixing members 8 are locked to the edge part 25c and the protruding part 25d of the chassis 25 at a plurality of places, and screwed to the upper horizontal frame 4 and both vertical frames 5 at a plurality of places using screws 19, and thereby the chassis 25 is fixed to the front cabinet 3. A detailed attaching structure of the fixing member 8 will be described below.

First, the attaching structure of the connector 7 will be described.

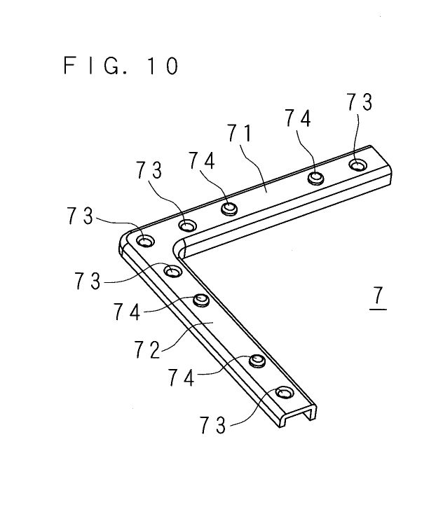

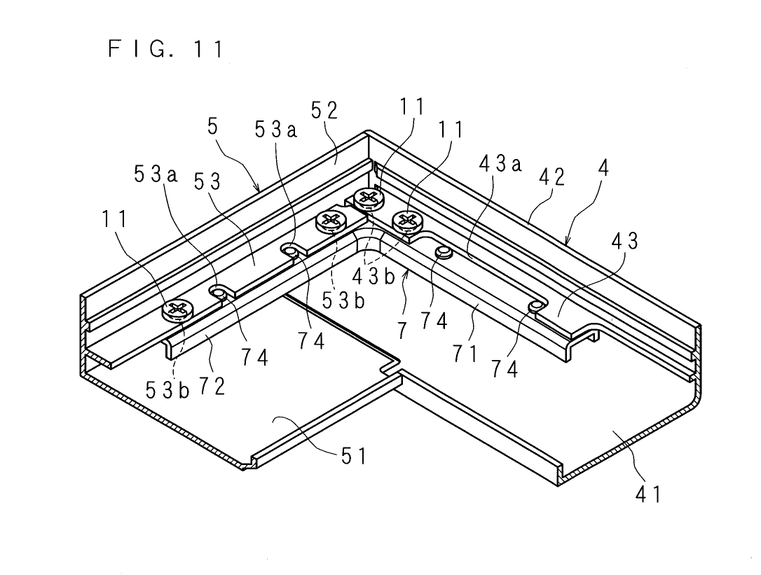

FIG. 10 is a perspective view illustrating the connector 7, and FIG. 11 is a perspective view illustrating a state in which the horizontal frame 4 and the vertical frame 5 are connected to each other by the connector 7.

The connector 7 is formed in an L shape as described above. A first plate part 71 and a second plate part 72 forming each side of L shape are formed in a narrow plate shape, and provided with short legs elongating from opposite end portions thereof in the short side direction. That is, the cross-section thereof is formed in a U shape in the short side direction. Thereby, the strength of the connector 7 may be secured, and the connector 7 may be lightened.

The connector 7 is provided with a female screw 73 formed at a corner of the L shape. Further, the first plate part 71 and the second plate part 72 are provided with female screws 73 and 73 respectively formed at the portions slightly near the tip ends from the corner female screw 73, and female screws 73 and 73 respectively formed at the tip end portion. The female screws 73 are formed by performing screw hole processing from front surfaces of the first plate part 71 and the second plate part 72, after low height cylindrical screw detent parts are formed on the rear surface of the first plate part 71 and the second plate part 72 by burring.

The first plate part 71 and the second plate part 72 are provided with small disc-shaped projections 74 and 74 respectively formed at portions slightly near the tip ends from the female screws 73 adjacent to the corner female screw 73. Similarly, the first plate part 71 and the second plate part 72 are provided with projections 74 and 74 respectively formed at portions slightly near the corner from the tip end side female screws 73.

In the first plate part 71 and the second plate part 72 of the connector 7, distances from the corner female screw 73 to the female screw 73, the projection 74, the projection 74, and the female screw 73, which are sequentially formed toward the tip end sides, are the same.

As illustrated in FIG. 11, the protruding part 53 of the vertical frame 5 is provided with screw insertion holes 53b and 53b which are respectively formed at a slightly corner side from the corner side notch 53a and at a slightly lower side from the lower side notch 53a. In addition, the protruding part 43 of the horizontal frame 4 is provided screw insertion holes 43b and 43b at a corner side and a slightly tip end side therefrom.

When connecting the horizontal frame 4 and the vertical frame 5 by the connector 7, first, the second plate part 72 is inserted between the protruding part 53 and the end edge covering part 51 in such a manner that the projections 74 and 74 of the second plate part 72 of the connector 7 are engaged into the notches 53a and 53a of the protruding part 53.

Then, with the projections 74 and 74 locked to the notches 53a and 53a to be fixed (positioned) thereto, the screws 11 and 11 are inserted into the screw insertion holes 53b and 53b, and screwed to two female screws 73 and 73 of the second plate part 72, and thereby the vertical frame 5 and the connector 7 are connected to each other.

With the tip end side projection 74 of the first plate part 71 of the connector 7 abutting a side wall of a side separated from the corner of the notch 43a of the protruding part 43, and the corner side projection 74 abutting a side wall of the notch 43a in the longitudinal direction, the first plate part 71 is inserted between the protruding part 43 and the end edge covering part 41.

Then, with the projections 74 locked to the notches 43a to be fixed (positioned) to them, the screws 11 and 11 are inserted into the screw insertion holes 43b and 43b, and screwed to the female screws 73 and 73 adjacent to the corner and thereto, and thereby the horizontal frame 4 and the connector 7 are connected to each other. By this, the horizontal frame 4 and the vertical frame 5 are connected to each other.

Hereinafter, a structure for attaching the display module 2 to the front cabinet 3 by the fixing member 8 will be described.

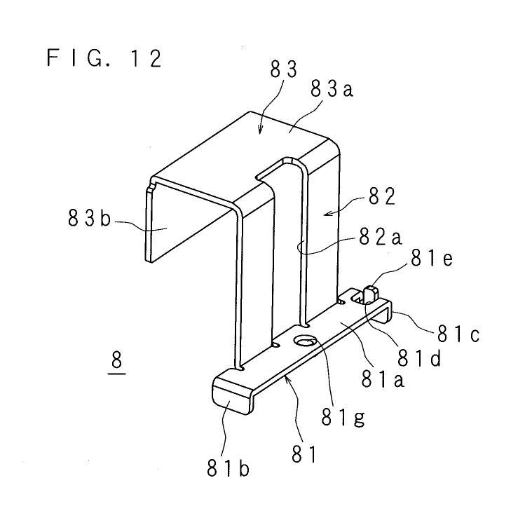

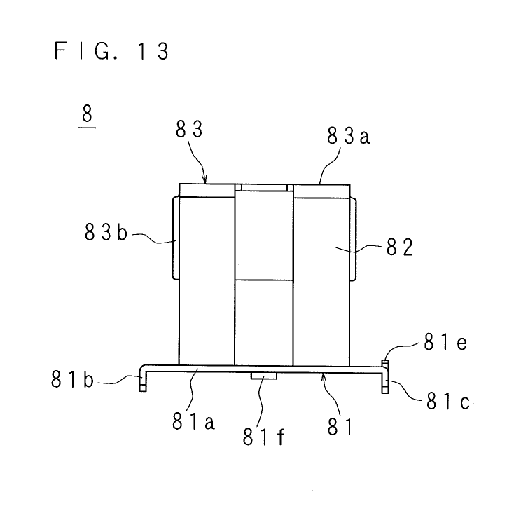

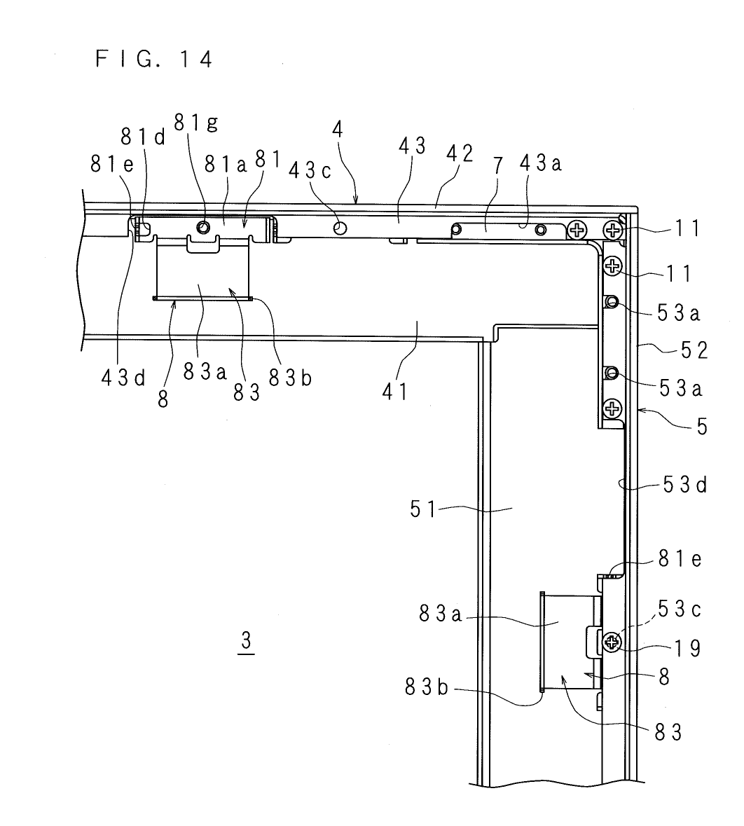

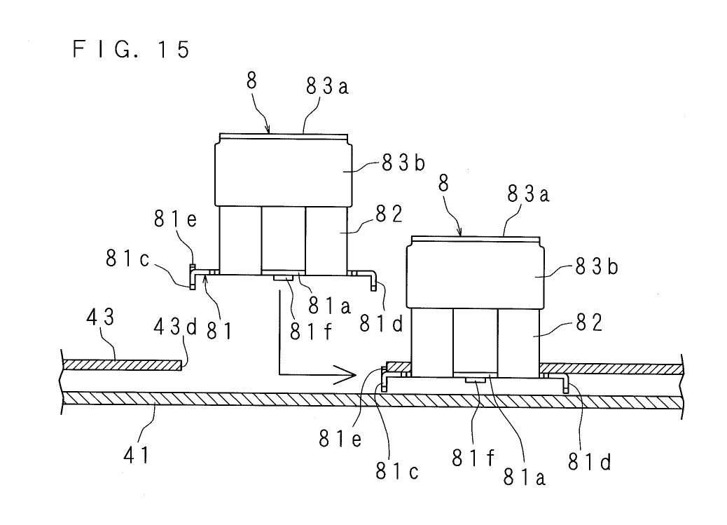

FIG. 12 is a perspective view illustrating the fixing member 8, FIG. 13 is a front view illustrating the fixing member 8, FIG. 14 is a plan view for describing the attachment of the fixing member 8 to the horizontal frame 4, and FIG. 15 is a side view for describing the attachment of the fixing member 8 to the horizontal frame 4. The display module 2 is not illustrated in FIGS. 14 and 15.

The fixing member 8 includes a screwing part 81 which extends in a narrow plate shape, an extension part 82 which is continuously arranged orthogonal to a long side of the screwing part 81 and extends in a plate shape, and a locking part 83 which is continuously arranged orthogonal to the extension part 82, and formed in an L shape in a side view.

The screwing part 81 includes a flat plate part 81a, leg parts 81b and 81c provided on opposite end portions of the flat plate part 81a in the longitudinal direction thereof, a notch 81d provided in the leg part 81c side of the flat plate part 81a, a stopper 81e provided in the leg part 81c so as to protrude upward in a mountain shape, a cylindrical low-height screw detent part 81f formed by burring in a central portion of a rear surface of the flat plate part 81a, and a female screw 81g formed by screw hole processing from the surface of the flat plate part 81a to the screw detent part 81f. The stopper 81e protrudes from the leg part 81c in a direction parallel to the direction in which the extension part 82 extends. The screwing part 81 has a substantially U-shaped cross-section in the longitudinal direction. Thereby, the fixing member 8 may be lightened while the strength thereof may be secured.

The extension part 82 is provided with a notch 82a in a central portion in a width direction. Thereby, the fixing member 8 may be lightened while the strength thereof may be secured.

The locking part 83 includes a first locking plate part 83a continuously arranged to the extension part 82, and a second locking plate part 83b continuously arranged orthogonal to the first locking plate part 83a.

The screwing part 81 is inserted between an outer surface (front side of the TV receiver 1) of the protruding part 43 (or 53) and a end edge covering part 41 (or 51) so as to be along the protruding part 43 (or 53) of the horizontal frame 4 (or the vertical frame 5), and screwed to the protruding part 43 (or 53) by a screw 19. At this time, the extension part 82 extends so as to be along the side of the display module 2, and with the tip end portion of the protruding part 25d of the chassis 25 abutting the front surface thereof, the first locking plate part 83a is disposed substantially parallel to the edge part 25c, and the second locking plate part 83b is, with the tip end portion thereof abutting a rear surface of the edge part 25c, disposed substantially parallel to the frame part 25b (see FIG. 6).

When the fixing member 8 is inserted between the protruding part 43 of the horizontal frame 4 and the end edge covering part 41, after arranging of the display module 2, it is not possible to directly insert the fixing member. Therefore, as illustrated in FIGS. 14 and 15, first, the screwing part 81 is inserted into the notch 43d from above the notch 43d.

Then, the screwing part 81 is slid to a corner side until the stopper 81e is locked to a side wall of the corner side of the notch 43d, and the screwing part 81 is inserted between the protruding part 43 and the end edge covering part 41.

With the sliding of the fixing member 8 limited by the stopper 81e and the fixing member 8 fixed (positioned) thereto, the screw 19 is inserted into the screw insertion hole 43c of the protruding part 43, and screwed to the female screw 81g, and thereby the fixing member 8 is fixed to the protruding part 43 (see FIG. 8). At this time, as illustrated in FIGS. 5 and 6, with the tip end portion of the protruding part 25d of the chassis 25 abutting the front surface of the first locking plate part 83a of the locking part 83, and the tip end portion of the second locking plate part 83b of the locking part 83 abutting the rear surface of the edge part 25c of the chassis 25, the chassis 25 is locked to the locking part 83, and thereby the display module 2 is fixed to the horizontal frame 4.

When the fixing member 8 is inserted between the protruding part 53 and the end edge covering part 51 of the vertical frame 5, as described above, first, the screwing part 81 is inserted into the notch 53d from above the notch 53d.

Then, the screwing part 81 is slid to a corner side until the stopper 81e is locked to a side wall of the side opposite to the corner of the notch 53d, and the screwing part 81 is inserted between the protruding part 53 and the end edge covering part 51.

With the sliding of the fixing member 8 limited by the stopper 81e and the fixing member 8 fixed (positioned) thereto, the screw 19 is inserted into the screw insertion hole 53c of the protruding part 53, and screwed to the female screw 81g, and thereby the fixing member 8 is fixed to the protruding part 53 (see FIG. 8). At this time, as similar to the structure of FIG. 6, with the tip end portion of the protruding part 25d of the chassis 25 abutting the first locking plate part 83a of the locking part 83, the chassis 25 is locked to the locking part 83, and thereby the display module 2 is fixed to the vertical frame 5.

As illustrated in FIG. 6, the screw 19 is inserted into the screw insertion hole 43c, and fastened to the female screw 81g provided in the screwing part 81.

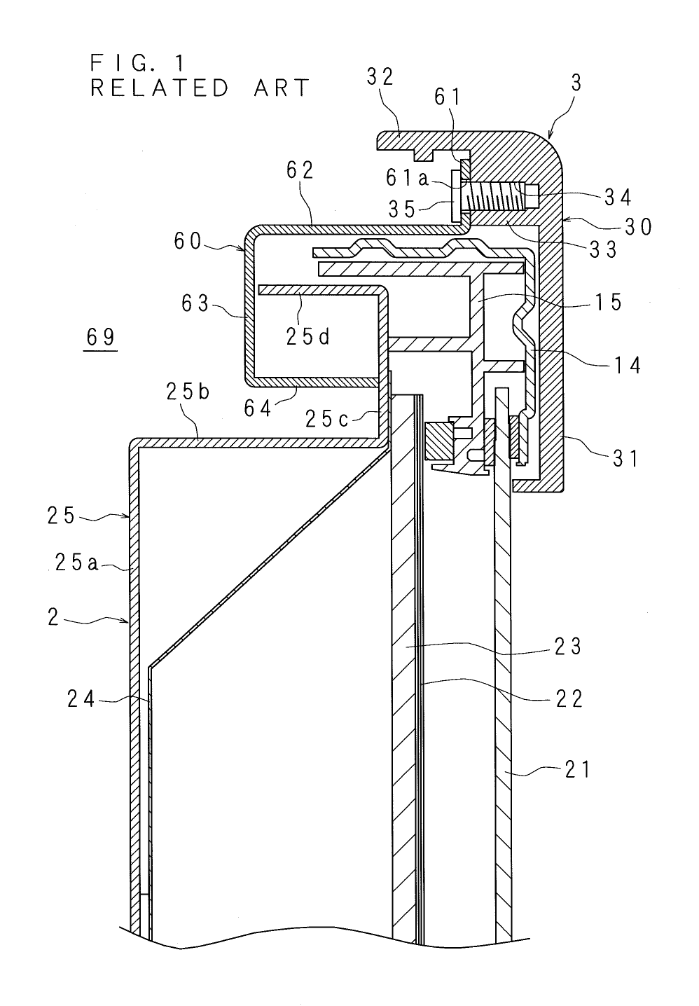

It can be seen that, in the fixing structure of the conventional TV receiver 69 illustrated in FIG. 1, it is necessary to increase the length of the screw 35, whereas in the fixing structure of the present embodiment illustrated in FIG. 6, it is possible to decrease the length of the screw 19. In the conventional fixing structure, since the screw 35 is screwed to the end edge covering part 31 of the horizontal frame 30 made of a soft metal such as aluminum, or the like, it is easy to cause screw damage, and thereby the protruded length of the projection 33 is increased, and the length of the screw 35 is also increased. Compared to this, in the present embodiment, since the screw 19 is screwed to the fixing member 8 made of a hard metal such as stainless steel, or the like, it is difficult to cause screw damage. Since the length of the screw 19 may be a length that the length of a screw detent part 81f or a slightly protruding length therefrom is added to the thickness of the protruding part 43 and the flat plate part 81a, the length thereof may be shortened. In the present embodiment, since the length of the screw 19 may be shortened, and the screwing part 81 of the fixing member 8 is disposed closer to the end edge covering parts 41 and 51 side, the set thickness of the TV receiver 1 may be decreased. In addition, even when the screw damage has occurred, it may be dealt with by replacing only the inexpensive fixing member 8 with a small size, and the replacement costs may be reduced. In addition, torque management of the fixing portion may be unified with the torque management of other general parts made of metal, and therefore productivity and workability may be improved.

Further, since tapping in the manufacture of the front cabinet 3 may be removed, it is possible to reduce costs in terms of this.

In addition, workability and maintenance management properties of the attachment of the display module 2 to the front cabinet 3 are good.

Further, in the conventional fixing structure, the root of the projection 33, or the like becomes thick, and flow of the material is not uniform during forming of the horizontal frame 30 and the vertical frame, as well as warping and sink are easily occur in the horizontal frame 30 and the vertical frame. Therefore, quality control becomes difficult, and it is necessary to decrease the extrusion rate during molding to cause a decrease in productivity. Whereas in the fixing structure of the present embodiment, since thick parts are not formed on the horizontal frame 4 and the vertical frame 5, the thickness of each part may be uniform as illustrated in FIG. 6. Therefore, the above-described problems are eliminated, and productivity may be improved, and thereby it is possible to obtain the front cabinet 3 with reliable quality. Furthermore, since the material costs may also be kept low, and costs of the horizontal frame 4 and the vertical frame 5 may be kept low as well as providing an improvement in yield, it is possible to reduce the overall cost of the TV receiver 1.

Furthermore, in the present embodiment, since thickening measures of the frames are not required, the width of the end edge covering parts 41 and 51 may be decreased, and it is possible to achieve narrowing of the frame.

### Embodiment 2

A TV receiver 68 according to Embodiment 2 of the present invention has the same configuration as the TV receiver 1 according to Embodiment 1, except that the structures of a chassis 25 and a fixing member 9 are different.

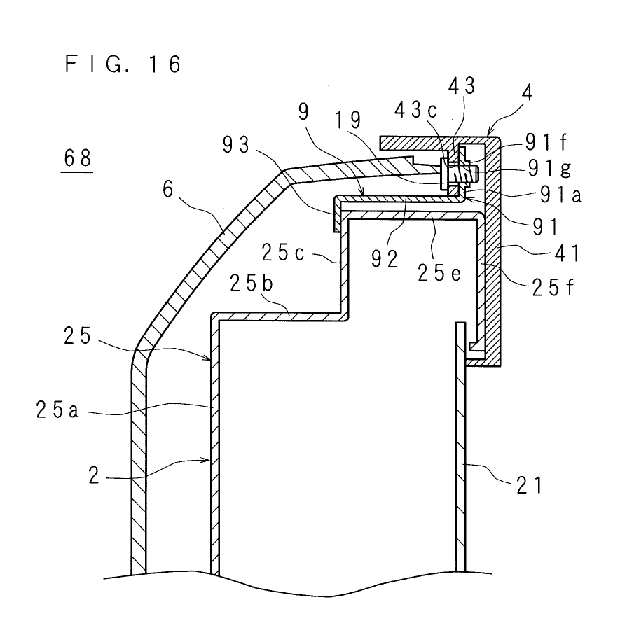

FIG. 16 is a partial longitudinal sectional view illustrating the TV receiver 68 according to Embodiment 2 of the present invention. In the drawings, the same parts as FIG. 6 will be denoted by the same reference numerals, and will not be described. In addition, the optical sheets 22, the diffusion plate 23, and the reflection sheet 24, and a holding structure of the display panel 21, the optical sheets 22, and the diffusion plate 23 will not be illustrated in FIG. 16.

The chassis 25 has a flat plate part 25a which is formed in a box shape formed by molding a metal plate, for example, and is formed in a rectangular shape, a frame part 25b which is formed so as to vertically rise from a peripheral edge of the flat plate part 25a, an edge part 25c which is disposed so as to protrude from an end edge portion of the frame part 25b to an outside of the box shape substantially parallel to the flat plate part 25a, a protruding part 25e which is disposed so as to protrude from an end edge portion of the edge part 25c substantially parallel to the frame part 25b, and a abutting part 25f which is continuously arranged orthogonal to the protruding part 25e and abuts the end edge covering part 41.

The fixing member 9 includes a screwing part 91 which extends in a narrow plate shape, an extension part 92 which is continuously arranged orthogonal to a long side of the screwing part 91 and extends in a plate shape, and a locking plate part 93 which is continuously arranged orthogonal to the extension part 92. The locking plate part 93 of the present embodiment is not the part in which the first locking plate part 83a and the second locking plate part 83b are continuously arranged in an L shape such as the locking part 83 according to Embodiment 1.

The screwing part 91 includes, similar to the screwing part 81, a flat part 91a, leg parts provided on opposite end portions of the flat part 91a in the longitudinal direction thereof, a notch provided in one leg part side of the flat part 91a, a stopper provided on one leg part so as to protrude upward in a mountain shape, a cylindrical low-height screw detent part 91f formed by burring in a central portion of a rear surface of the flat part 91a, and a female screw 91g formed by screw hole processing from the surface of the flat part 91a to the screw detent part 91f.

In the present embodiment, similar to the Embodiment 1, the screwing part 91 of the fixing member 9 is inserted into the notch 43d from above the notch 43d of the horizontal frame 4. Then, the screwing part 91 is slid to a corner side until the stopper is locked to a side wall of the corner side of the notch 43d, and the screwing part 91 is inserted between the protruding part 43 and the end edge covering part 41.

With the sliding of the fixing member 9 limited by the stopper and the fixing member 9 fixed (positioned) thereto, the screw 19 is inserted into the screw insertion hole 43c of the protruding part 43, and screwed to the female screw 91g, and thereby the fixing member 9 is fixed to the protruding part 43. At this time, the locking plate part 93 is locked to an end portion of the protruding part 25e side of the edge part 25c of the chassis 25. Thereby, the display module 2 is fixed to the horizontal frame 4.

In the vertical frame 5, similar to the horizontal frame 4, the display module 2 is fixed thereto by the fixing member 9.

Then, the rear cabinet 6 is fitted to the front cabinet 3.

In the present embodiment, since the female screw 91g is provided in the fixing member 9 using a harder metal than the horizontal frame 4 and the vertical frame 5, occurrence of defective products due to fastening defect such as screw damage, or the like may be suppressed, and even when replacement of the fixing member is required due to occurrence of the screw damage, only the fixing member 9 with the damaged screw may be replaced, and therefore replacement costs and F costs may be reduced. In addition, since the horizontal frame 4 and the vertical frame 5 do not need tapping, and have a uniform cross-section shape, the productivity of the horizontal frame 4 and the vertical frame 5 may be improved, and the volume thereof is decreased, such that material costs may be reduced, and thereby overall cost may be reduced. Further, poor appearance and quality such as impairment of appearance caused by that the shape of a thick portion is reflected, and occurrence of warping, or the like may be suppressed. Furthermore, since thickening measures of the horizontal frame 4 and the vertical frame 5 are not required, it is possible to achieve narrowing of the frame. In addition, a length of the screw 19 may be shortened, and the set thickness of the TV receiver 68 may be reduced by arranging the screwing part 91 of the fixing member 9 closer to the end edge covering parts 41 and 51 side.

### Embodiment 3

A TV receiver according to Embodiment 3 of the present invention has the same configuration as the TV receiver 1 according to Embodiment 1, except that the structure of a fixing member 18 is different from the fixing member 8 according to Embodiment 1.

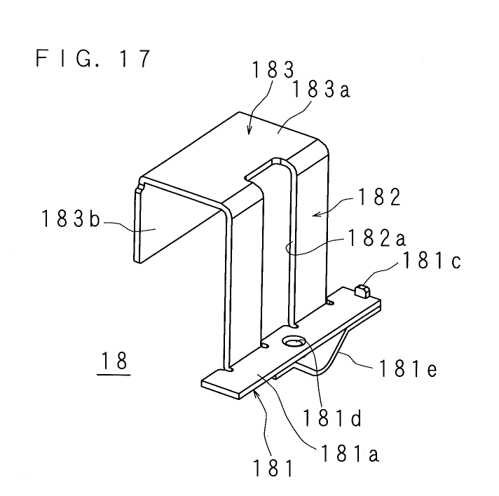

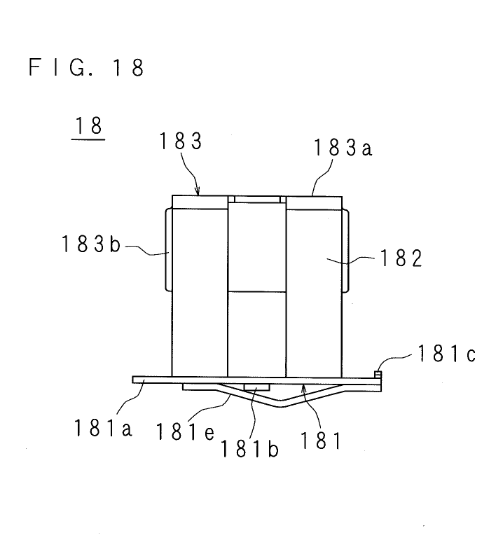

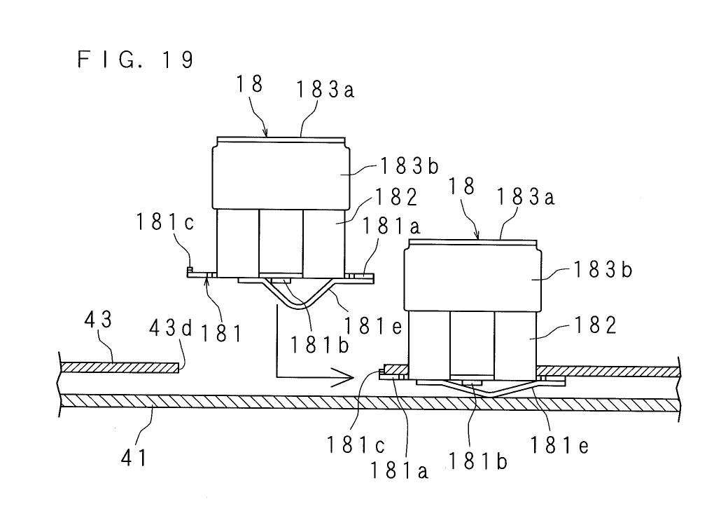

FIG. 17 is a perspective view illustrating the fixing member 18, FIG. 18 is a front view illustrating the fixing member 18, and FIG. 19 is a side view for describing the attachment of the fixing member 18 to the horizontal frame 4. In FIG. 19, the same parts as FIG. 15 will be denoted by the same reference numerals, and will not be described. In addition, the display module 2 will not be illustrated.

The fixing member 18 includes a screwing part 181 which extends in a narrow plate shape, an extension part 182 which is continuously arranged orthogonal to a long side of the screwing part 181 and extends in a plate shape, and a locking part 183 which is continuously arranged orthogonal to the extension part 182, and formed in an L shape in a side view.

The screwing part 181 includes a flat part 181a, a cylindrical low-height screw detent part 181b formed by burring in a central portion of a rear surface of the flat part 181a, a stopper 181c provided on one end portion of the flat part 181a so as to protrude upward in a mountain shape, and a female screw 181d formed by screw hole processing from the surface of the flat part 181a to the screw detent part 181b. The stopper 181c protrudes in a direction parallel to the direction in which the extension part 182 extends.

The flat part 181a is provided with a plate spring 181e attached thereto in a state of being convex downward.

The extension part 182 is provided with a notch 182a in a central portion in the width direction. Thereby, the fixing member 18 may be lightened while the strength thereof may be secured.

The locking part 183 includes a first locking plate part 183a which is continuously arranged to the extension part 182, and a second locking plate part 183b which is continuously arranged orthogonal to the first locking plate part 183a.

The screwing part 181 is inserted between the outer surface (front side of the TV receiver 1) of the protruding part 43 and the end edge covering part 41 so as to be along the protruding part 43 of the horizontal frame 4. At this time, after arranging of the display module 2, it is not possible to directly insert the fixing member 18. Therefore, as illustrated in FIG. 19, first, the screwing part 181 is inserted into the notch 43d from above the notch 43d. Then, the screwing part 181 is slid to a corner side until the stopper 181c is locked to a side wall of the corner side of the notch 43d, and the screwing part 181 is inserted between the protruding part 43 and the end edge covering part 41.

The plate spring 181e is located between the flat part 181a and the end edge covering part 41, and the flat part 181a is locked to the protruding part 43 by a biasing force to the protruding part 43. Even when there are dispersions in the width dimension of the horizontal frame 4, that is, dispersions are present between the protruding part 43 and the end edge covering part 41, the screwing part 181 is locked to the protruding part 43 in a state in which the dispersions are absorbed by the plate spring 181e.

With the sliding of the fixing member 18 in the lateral direction limited by the stopper 181c and the fixing member 18 fixed (positioned) thereto, the screw 19 is inserted into the screw insertion hole 43c of the protruding part 43, and fastened to the female screw 181d, and thereby the fixing member 18 is fixed to the protruding part 43 (similar to the structure of FIG. 8).

At this time, the extension part 182 extends so as to be along the side of the display module 2, and with the tip end portion of the protruding part 25d of the chassis 25 abutting the front surface thereof, the first locking plate part 183a is disposed substantially parallel to the edge part 25c, and the second locking plate part 183b is, with the tip end portion thereof abutting the rear surface of the edge part 25c, disposed substantially parallel to the frame part 25b (similar to the structure of FIG. 6).

When the fixing member 18 is inserted between the protruding part 53 and the end edge covering part 51 of the vertical frame 5, as described above, first, the screwing part 181 is inserted into the notch 53d from above the notch 53d.

Then, the screwing part 181 is slid to a corner side until the stopper 181c is locked to the side wall of the side opposite to the corner of the notch 53d, and the screwing part 181 is inserted between the protruding part 53 and the end edge covering part 51 (similar to the structure of FIG. 8). The plate spring 181e is located between the flat part 181a and the end edge covering part 51, and the flat part 181a is locked to the protruding part 53 by a biasing force to the protruding part 53. Even when there are dispersions in the width dimension of the vertical frame 5, that is, dispersions are present between the protruding part 53 and the end edge covering part 51, the screwing part 181 is locked to the protruding part 53 in a state in which the dispersions are absorbed by the plate spring 181e.

With the screwing part 181 locked to the protruding part 53 by the plate spring 181e, the sliding of the fixing member 18 in the longitudinal direction limited by the stopper 181c and the fixing member 18 fixed (positioned) thereto, the screw 19 is inserted into the screw insertion hole 53c of the protruding part 53, and fastened to the female screw 181d, and thereby the fixing member 18 is fixed to the protruding part 53. At this time, similar to the structure of FIG. 6, with the tip end portion of the protruding part 25d of the chassis 25 abutting the first locking plate part 183a of the locking part 183, the chassis 25 is locked to the locking part 183, and thereby the display module 2 is fixed to the vertical frame 5.

In the present embodiment, since the fixing member 18 has the plate spring 181e, as described above, dispersions in the width dimension of the horizontal frame 4 and the vertical frame 5 are absorbed.

In addition, with respect to a TV receiver having a different width of the horizontal frame and the vertical frame, it is possible to share the fixing member, and reduce manufacturing costs.

Furthermore, in the above-described embodiment, it is not limited to the case in which the plate spring 181e is provided on the flat part 181a. Any other kind of spring such as a coil spring may be used for applying the biasing force as similar to the plate spring 181e.

As described above, the display device according to the present invention includes a display unit (2) which displays an image on the front surface, a rectangular frame (3) covering the peripheral edge parts of the display unit (2), and a fixing member (8, 9 and 18) having: a screwing part (81, 91 and 181) to which the frame (3) is screwed; an extension part (82, 92 and 182) which extends to a rear side along a side part of the display unit; and a locking part (83, 93 and 183) which is locked to the rear side of the display unit (2), wherein the screwing part (81, 91 and 181) is provided with a female screw(81g, 91g and 181d) for screwing the frame (3).

According to the present invention, since the female screws (81g, 91g and 181d) are provided in the fixing members (8, 9 and 18), using a harder metal than the frame (3), occurrence of defective products due to fastening defect such as screw damage, or the like may be suppressed, and even when replacement of the connector is required due to occurrence of the screw damage, only the fixing members (8, 9 and 18) with the damaged screw may be replaced, and therefore replacement costs (F costs) may be reduced. In addition, torque management of the connecting portion may be made common with the torque management of other general parts made of metal, and therefore productivity and workability may be improved.

In addition, tapping in the manufacture of the frame (3) may be removed, and therefore overall cost may be reduced.

Further, a length of the screw (19) may be shortened, and the set thickness may be reduced by arranging the fixing members (8, 9 and 18) closer to the frame (3) side. Furthermore, since thickening measures of the frame (3) are not required, it is possible to achieve narrowing of the frame.

In addition, since the frame (3) may have a uniform cross-section shape, the productivity of the frame (3) may be improved, and since the volume thereof is decreased, such that material costs may be reduced, and thereby overall cost may be reduced. Further, poor appearance such as impairment of appearance caused by that the shape of a thick portion is reflected, or the like may be suppressed, without occurring the warping of the frame in the longitudinal direction, while having excellent appearance quality.

Further, workability and maintenance management properties of the attachment of the display unit (2) to the frame (3) are good.

In the display device according to the present invention, the frame (3) has an end edge covering part (41 and 51) which covers an end edge part of the front surface of the display unit (2), and a side covering part (42 and 52) which covers a side part of the display unit (2), the side covering part (42 and 52)has a protruding part (43 and 53) which protrudes substantially parallel to the end edge covering part (41 and 51) on the inward side, the protruding part (43 and 53) is provided with an insertion hole (43c and 53c) into which a screw (19) is inserted, and the screwing part (81, 91 and 181) is configured to be inserted between the protruding part (43 and 53) and the end edge covering part (41 and 51) so that the protruding part (43 and 53) is screwed to the screwing part (81, 91 and 181).

According to the present invention, it is possible to further decrease the thickness (set thickness) of the front cabinet in front and back direction.

In the display device according to the present invention, the protruding part (43 and 53) is provided with an insertion hole (43d and 53d) into which the fixing member (8, 9 and 18) is inserted, and the fixing member (8, 9 and 18) is configured to be inserted from the insertion hole (43d and 53d) so that the screwing part (81, 91 and 181) is moved along the protruding part (43 and 53).

According to the present invention, the fixing members (8, 9 and 18) may be easily attached to the frame (3).

In the display device according to the present invention, the screwing part (81, 91 and 181) is provided with a stopper (81e and 181c) which is locked to a side of the insertion hole (43d and 53d).

According to the present invention, the frame (3) may be fixed (positioned) to the fixing members (8, 9 and 18) and screwed thereto.

In the display device according to the present invention, the screwing part (81 and 91) has a U-shaped cross-section in a longitudinal direction.

According to the present invention, the frame (3) may be lightened while the strength thereof may be secured.

In the display device according to the present invention, the screwing part (181) has a flat plate part (181a) which has a rectangular shape, and a spring (181e) which is provided on the rear surface of the flat plate part to press the flat plate part (181a) to the protruding part (43 and 53).

According to the present invention, since the screwing part (181) has the spring (181e), and the spring (181e) is located between the protruding parts (43 and 53) and the end edge covering parts (41 and 51), the screwing part (181) may be successfully locked to the protruding parts (43 and 53) and dispersions in the width dimension of the frame (3) may be absorbed.

In addition, with respect to a TV receiver having a different width of the frame (3), it is possible to share the fixing member, and reduce manufacturing costs.

In the display device according to the present invention, the locking part (83, 93 and 183) has an L-shape when viewed from a side.

According to the present invention, the fixing members (8, 9 and 18) may be further reliably locked with respect to display unit (2).

The television receiver (1, 68) according to the present invention may include: the above-described display device; and a receiving part (12) which receives a television broadcast, wherein the display device is configured to display an image based on the television broadcast received by the receiving part (12).

According to the present invention, any one of the above-described display device displays an image thereon based on the television broadcast.

As this description may be embodied in several forms without departing from the spirit of essential characteristics thereof, the present embodiment is therefore illustrative and not restrictive, since the scope is defined by the appended claims rather than by the description preceding them, and all changes that fall within metes and bounds of the claims, or equivalence of such metes and bounds thereof are therefore intended to be embraced by the claims. For example, the configurations of the fixing members 8, 9 and 18 are not limited to the configurations described in Embodiments 1 to 3. In addition, the front cabinet 3 is not limited to the case in which the horizontal frame 4 and the vertical frame 5 are connected each other by the connector 7.

1-8. (canceled)

9. A display device which comprises a display unit which displays an image on the front surface, a rectangular frame covering the peripheral edge part of the display unit, and a fixing member having: a screwing part to which the frame is screwed; an extension part which extends to a rear side along a side part of the display unit; and a locking part which is locked to the rear side of the display unit,
wherein the screwing part is provided with a female screw for screwing the frame.

10. The display device according to claim 9, wherein the frame has an end edge covering part which covers an end edge part of the front surface of the display unit, and a side covering part which covers a side part of the display unit,
the side covering part has a protruding part which protrudes substantially parallel to the end edge covering part on the inward side,
the protruding part is provided with an insertion hole into which a screw is inserted, and
the screwing part is configured to be inserted between the protruding part and the end edge covering part so that the protruding part is screwed to the screwing part.

11. The display device according to claim 10, wherein the protruding part is provided with an insertion hole into which the fixing member is inserted, and the fixing member is configured to be inserted from the insertion hole so that the screwing part is moved along the protruding part.

12. The display device according to claim 11, wherein the screwing part is provided with a stopper which is locked to a side of the insertion hole.

13. The display device according to claim 11, wherein the screwing part has a U-shaped cross-section in a longitudinal direction.

14. The display device according to claim 12, wherein the screwing part has a U-shaped cross-section in a longitudinal direction.

15. The display device according to claim 11, wherein the screwing part has a flat plate part which has a rectangular shape, and a spring which is provided on the rear surface of the flat plate part to press the flat plate part to the protruding part.

16. The display device according to claim 12, wherein the screwing part has a flat plate part which has a rectangular shape, and a spring which is provided on the rear surface of the flat plate part to press the flat plate part to the protruding part.

17. The display device according to claim 11, wherein the locking part has an L-shape when viewed from a side.

18. The display device according to claim 12, wherein the locking part has an L-shape when viewed from a side.

19. The display device according to claim 13, wherein the locking part has an L-shape when viewed from a side.

20. The display device according to claim 15, wherein the locking part has an L-shape when viewed from a side.

21. A television receiver comprising:
the display device according to claim 11; and
a receiving part which receives a television broadcast,
wherein the display device is configured to display an image based on the television broadcast received by the receiving part.

22. A television receiver comprising:
the display device according to claim 12; and
a receiving part which receives a television broadcast,
wherein the display device is configured to display an image based on the television broadcast received by the receiving part.

23. A television receiver comprising:
the display device according to claim 13; and
a receiving part which receives a television broadcast,
wherein the display device is configured to display an image based on the television broadcast received by the receiving part.

24. A television receiver comprising:
the display device according to claim 14; and
a receiving part which receives a television broadcast,
wherein the display device is configured to display an image based on the television broadcast received by the receiving part.

25. A television receiver comprising:
the display device according to claim 15; and
a receiving part which receives a television broadcast,
wherein the display device is configured to display an image based on the television broadcast received by the receiving part.

26. A television receiver comprising:
the display device according to claim 16; and
a receiving part which receives a television broadcast,
wherein the display device is configured to display an image based on the television broadcast received by the receiving part.

27. A television receiver comprising:
the display device according to claim 17; and
a receiving part which receives a television broadcast,
wherein the display device is configured to display an image based on the television broadcast received by the receiving part.

28. A television receiver comprising:
the display device according to claim 18; and
a receiving part which receives a television broadcast,
wherein the display device is configured to display an image based on the television broadcast received by the receiving part.
